(19) United States
(12) Patent Application Publication
(10) Pub. No.: US 2009/0176371 A1
(43) Pub. Date: Jul. 9, 2009

(54) Method For The Preferential Polishing Of Silicon Nitride Versus Silicon Oxide

(75) Inventors: Suryadevara V. Babu, Potsdam, NY (US); Anita Natarajan, Potsdam, NY (US)

Correspondence Address: RANKIN, HILL & CLARK LLP, 925 EUCLID AVENUE, SUITE 700, CLEVELAND, OH, 44115-1405, US

(73) Assignees: CLARKSON UNIVERSITY, Potsdam, NY (US); INFOTONICS TECHNOLOGY CENTER INC., Canandaigua, NY (US)

(21) Appl. No.: 12/266,595

(22) Filed: Nov. 7, 2008

Related U.S. Application Data
(63) Continuation of application No. 11/562,447, filed on Nov. 22, 2006, now abandoned.

(51) Int. Cl. H01L 21/304

(52) U.S. Cl. 438/693; 257/E21.23

(57) ABSTRACT

The present invention provides a method of removing silicon nitride in preference to silicon dioxide by CMP. The method utilizes a polishing slurry that includes colloidal silica abrasive particles dispersed in water and an additive that suppresses the silicon dioxide removal rate but enhances the silicon nitride removal rate. In one embodiment of the invention, the additive is lysine, which is effective at a pH of about 9, or arginine, which is effective at a pH of about 8. In another embodiment of the invention, the additive is lysine mono hydrochloride in combination with picolinic acid, which is effective at a pH of about 8, or arginine in combination with picolinic acid, which is effective at a pH of about 9.

The U.S. Government has a paid-up license in this invention and the right in limited circumstances to require the patent owner to license others on reasonable terms as provided for by the terms of Grant No. NAG3-2744 awarded by NASA. The Government has certain rights in the invention.

### BACKGROUND OF THE INVENTION

1. Field of Invention The present invention relates to compositions and methods for selectively removing silicon nitride in preference to silicon dioxide by chemical-mechanical polishing.

2. Description of Related Art

Silicon nitride has been widely used as a barrier layer and/or as an etch stop layer to protect underlying devices from being removed during chemical-mechanical polishing (CMP) in integrated circuit (IC) fabrication. Accordingly, most CMP polishing slurries and processes have attempted to minimize the silicon nitride removal rate while attaining relatively high removal rates for other layers. CMP polishing slurries and processes that are highly selective for silicon dioxide in preference to silicon nitride have been developed and utilized in the shallow trench isolation (STI) manufacturing process.

There are emerging technologies in the semiconductor industry where it would be advantageous to have CMP slurries and processes whereby the removal rate of silicon nitride is greater than the removal rate of silicon dioxide. Suppressing the silicon dioxide removal rate while at the same time achieving a higher silicon nitride removal rate is immensely challenging because the removal of silicon nitride via CMP typically follows a mechanism in which the surface of the silicon nitride is hydrolyzed to silicon dioxide (Si₃N₄+6H₂O→3SiO₂+4NH₃), which is then removed during CMP. Accordingly, additives conventionally used in CMP slurries to suppress the silicon dioxide removal rate tend to suppress the silicon nitride removal rate because the silicon nitride is converted to silicon dioxide and removed as such.

### SUMMARY OF INVENTION

The present invention provides a method of removing silicon nitride in preference to silicon dioxide by CMP. The method utilizes is a polishing slurry that includes colloidal silica abrasive particles dispersed in water, and an additive that suppresses the silicon dioxide removal rate but enhances the silicon nitride removal rate particularly when used with the silica abrasives. In one embodiment of the invention, the additive is lysine, which is effective at a pH of about 9, or arginine, which is effective at a pH of about 8. In another embodiment of the invention, the additive is lysine mono hydrochloride in combination with picolinic acid, which is effective at a pH of about 8, or arginine in combination with picolinic acid, which is effective at a pH of about 9. Applicants hypothesize that the positively charged amino acid constituent of the additive (arginine, lysine and lysine mono hydrochloride) becomes adsorbed on the negatively charged silica abrasive particles and the silicon dioxide film at pH 8 and 9. Suppression of the removal rate of silicon dioxide during CMP is attributed to electrostatic repulsion. In picolinic acid containing slurries, picolinic acid being negatively charged at pH>7, does not adsorb on the silica abrasive or silicon dioxide film, and therefore does not significantly affect the silicon dioxide removal rates.

In the case of silicon nitride film polish rates, it is interesting to note that even though lysine adsorbs to both the silica abrasives and the silicon nitride film at pH 9, the silicon nitride removal rate is enhanced. This is in contrast to observations in our previous work where lysine when used with ceria (CeO2) abrasives at pH 9 suppressed the silicon nitride removal rate, W. G. America and S. V. Babu, Electrochemical and Solid State Letters, 7 (12) G327-G330 (2004). This highlights the importance of silica abrasives used in the slurry. At pH 8, arginine and lysine may not adsorb on the silicon nitride film as it is far from the IEP of silicon nitride (9.7). However, these additives do adsorb on to the silica abrasive at pH 8, and the additive coated silica abrasive continues to enhance the silicon nitride removal rate. The additive picolinic acid adsorbs on the silicon nitride film surface at pH 8 and 9, but the use of silica abrasives in the slurry results in an increase in the silicon nitride removal rate.

The foregoing and other features of the invention are hereinafter more fully described and particularly pointed out in the claims, the following description setting forth in detail certain illustrative embodiments of the invention, these being indicative, however, of but a few of the various ways in which the principles of the present invention may be employed.

### DETAILED DESCRIPTION OF THE PREFERRED EMBODIMENTS

The method of the present invention comprises disposing a polishing slurry between a polishing pad and a surface comprising silicon nitride (sometimes abbreviated as “Si₃N₄”) and pressing the polishing pad against the surface while the polishing pad and surface are moving relative to each other with the polishing slurry disposed therebetween to remove silicon nitride from the surface. Silicon nitride is removed from the surface by CMP at a faster rate than any silicon dioxide that may be present at the interface between the surface and the polishing pad. Desirably the ratio of the removal rate of silicon dioxide to the removal rate of silicon nitride is about 0.5 or less, preferably about 0.3 or less, and most preferably 0.2 or less.

The silicon nitride can be in the form of a surface film, which may overly or lay next to a film of silicon dioxide. The surface may also comprise one or more additional materials, such as polysilicon, for example.

The polishing slurry used in accordance with the method of the invention preferably comprises colloidal silica abrasive particles dispersed in water and an additive that suppresses the silicon dioxide removal rate but enhances the silicon nitride removal rate. Desirable additive compounds include organic compounds containing an alpha-amino carboxylic acid functional group and an additional functional group, wherein the additional functional group includes an amino group or a guanidine group.

Organic compounds that have an amino group and an acid group attached to the same carbon are referred to as alpha-amino carboxylic acids. Many alpha-amino carboxylic acid compounds are known and there are twenty “natural” amino acids, that is, amino acids that are used as basic components of proteins in living organisms.

In addition to an amino acid functional group, desirable additive compounds have an additional functional group, which can be protonated and consequently can acquire a positive charge. Useful functional groups include amino groups and guanidine groups. In particular, primary amino groups having a pKa of about 9.0 or greater are desirable.

An example of a compound having both an alpha-amino carboxylic acid functional group and an additional amino functional group is lysine. Arginine is an example of a compound having both an alpha-amino carboxylic acid functional group and an additional guanidine substituent. In one embodiment the additive compound is selected from the group consisting of arginine, lysine and lysine mono hydrochloride. Illustrative useful compounds are listed below.

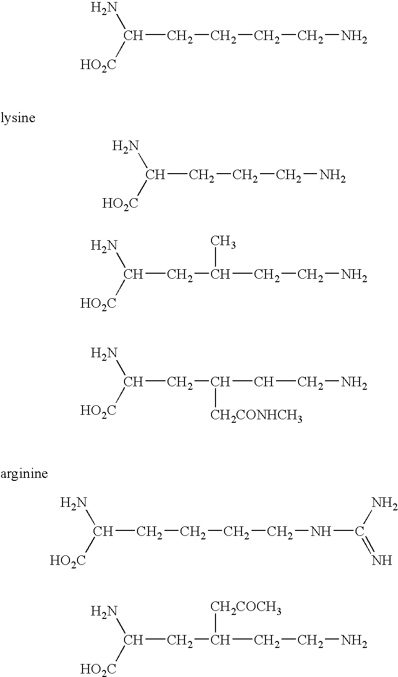

In one embodiment of the invention, the additive includes an alpha-amino carboxylic acid compound containing an additional amino group, and the pH of the slurry is in the range of about 8.5 to about 9.5 (about 9±0.5). In another embodiment of the invention, the additive includes an alpha-amino carboxylic acid compound containing an additional amino group, picolinic acid or a derivative thereof, and the pH of the slurry is in the range of about 7.5 to about 8.5, that is, about 8±0.5.

In another embodiment of the invention, the additive includes an alpha-amino carboxylic acid compound containing an guanidine substituent group, and the pH of the slurry is in the range of about 7.5 to about 8.5 (about 8±0.5). In another embodiment of the invention, the additive includes an alpha-amino carboxylic acid compound containing a guanidine substituent group, picolinic acid or a derivative thereof, and the pH of the slurry is in the range of about 8.5 to about 9.5, that is, about 9±0.5.

In one embodiment of the invention, the additive is lysine, which is effective at a pH of about 9, or arginine, which is effective at a pH of about 8. In another embodiment of the invention, the additive is lysine mono hydrochloride in combination with picolinic acid, which is effective at a pH of about 8, or arginine in combination with picolinic acid, which is effective at a pH of about 9.

Useful derivatives of picolinic acid include compounds of formula 1, wherein r₁-r₄ independently represent hydrogen or a substituent such as, for example, a substituted or unsubstituted alkyl group, such as a methyl or ethyl group, a halogen, such as a chloro group, or a substituted or unsubstituted aromatic group such as a phenyl group. In one desirable embodiment, r₁-r₄ represent hydrogen and formula 1 represents picolinic acid.

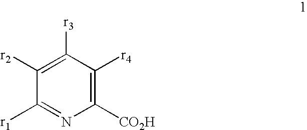

The colloidal silica particles present in the polishing slurry preferably have a mean average diameter of from about 25 nm to about 75 nm, and more preferably of about 50 nm.

The amino acid component of the additive is preferably present in an amount from about 1.0% to about 4.0% by weight, and more preferably, from about 2.0% to about 3.0% by weight. Picolinic acid or a derivative thereof, when present, is typically added in an amount from about 1.0% to about 3.0% by weight. The composition of the polishing pad is not per se critical, and conventional polishing equipment can be used.

Applicants hypothesize that at both pH 8 and 9, arginine and lysine are positively charged, while the silicon dioxide surface (i.e., the surface of the colloidal silica abrasive particles and any silicon dioxide surface films) is negatively charged. Therefore, due to electrostatic interactions, the positively charged amino acid component will adsorb onto the colloidal silica abrasive as well as on any silicon dioxide surface films. This causes an electrostatic repulsion between the additive adsorbed abrasive and the silicon dioxide surface film, which results in low silicon dioxide removal rates. However, it is interesting to note that even when lysine adsorbs to the silicon nitride surface at pH 9, and lysine/arginine may not adsorb on to the silicon nitride surface at pH 8 (pH 8 being far from the IEP of silicon nitride, 9.7), the additive coated silica abrasive results in an increase in the silicon nitride removal rate in both cases.

Picolinic acid, which has a pKa of about 6, is negatively charged at a pH of about 8. Thus, picolinic acid repels the SiO₂ surface but adsorbs on the silicon nitride surface, and colloidal silica abrasives when used with picolinic acid in the slurry result in enhanced silicon nitride removal rate.

Another aspect of the invention includes a polishing slurry including colloidal silica abrasive particles dispersed in water at a pH in the range of about 7.5 to about 9.5; a first compound comprising an organic compound containing an alpha-amino acid functional group and an additional functional group, wherein said additional functional group comprises an amino group or a guanidine group; and a second compound comprising picolinic acid or a derivative thereof.

The following examples are intended to illustrate the invention without limiting it in any way. All raw materials referenced in the examples are standard pigment grade powders unless otherwise indicated.

### Example 1

Six CMP slurries were separately prepared by dispersing 10% by weight of colloidal silica particles having a mean size of about 50 nm in water. The additives listed in Table 1 below in weight percent were added to the respective CMP slurries (where “Lys” means lysine; “Arg” means arginine; “LysHCl” means lysine mono hydrochloride; and “Pico” means picolinic acid). The pH of the CMP slurries was adjusted as shown in Table 1 below by adding a sufficient amount of potassium hydroxide.

The CMP slurries were then separately used to polish blanket silicon dioxide and silicon nitride films for one minute using a Westech-372 polisher using a down force as shown in Table 1, a carrier/platen speed of 75/75 rpm, a slurry flow rate of 200 ml/min and an IC-1400, k-groove polishing pad. The polishing pad was conditioned for one minute before every polishing experiment. The removal rates of reported in Table 1 are an average of the removal rates of two wafers each of silicon dioxide and silicon nitride.

TABLE 1

| Sam- | | | Operating | SiO₂ RR | Si₃N₄ RR | Selectivity |
|---|---|---|---|---|---|---|
| ple | Additive | pH | Pressure | (nm/min) | (nm/min) | SiO₂:Si₃N₄ |
| 1A | None | 9 | 4 psi | 32 ± 8 | 12 ± 3 | ~2.7 |
| 1B | Lys - | 9 | 4 psi | 8 ± 4 | 24 ± 4 | 0.33 |
| | 1 wt % | | | | | |
| 1C | Lys | 9 | 4 psi | 6 ± 5 | 16 ± 3 | 0.375 |
| | 2 wt % | | | | | |
| 1D | Arg - | 8 | 4 psi | 5 ± 3 | 35 ± 4 | 0.14 |
| | 2 wt % | | | | | |
| 1E | Arg - | 8 | 4 psi | 7 ± 4 | 25 ± 2 | 0.28 |
| | 1 wt % | | | | | |
| 1F | LysHCL- | 8 | 2 psi | 16 ± 4 | 37 ± 6 | 0.43 |
| | 2 wt % | | | | | |
| | Pico- | | | | | |
| | 1 wt % | | | | | |

The data in Table 1 shows that it is possible to use colloidal silica-based slurries to remove silicon nitride in preference to silicon dioxide by CMP. Sample 1D, which contained 2% by weight arginine, showed a 7:1 silicon nitride to silicon dioxide selectivity.

### Example 2

Four CMP slurries were separately prepared by dispersing 10% by weight of colloidal silica particles having a mean size of about 50 nm in water. The additives listed in Table 2 below in weight percent were added to the respective CMP slurries (where “Arg” means arginine; “LysHCl” means lysine mono hydrochloride; and “Pico” means picolinic acid). The pH of the CMP slurries was adjusted as shown in Table 2 below by adding a sufficient amount of potassium hydroxide.

The CMP slurries were then separately used to polish blanket silicon dioxide and silicon nitride films for one minute using a Westech-372 polisher using a down force as shown in Table 2, a carrier/platen speed of 75/75 rpm, a slurry flow rate of 200 ml/min and an IC-1400, k-groove polishing pad. The polishing pad was conditioned for one minute before every polishing experiment. The removal rates of reported in Table 2 are an average of the removal rates of two wafers each of silicon dioxide and silicon nitride.

TABLE 2

| Sam- | | | Operating | SiO₂ RR | Si₃N₄ RR | Selectivity |
|---|---|---|---|---|---|---|
| ple | Additive | pH | Pressure | (nm/min) | (nm/min) | SiO₂:Si₃N₄ |
| 2A | Arg - | 8 | 4 psi | 21 ± 5 | 42 ± 10 | 0.5 |
| | 1 wt % | | | | | |
| | Pico - | | | | | |
| | 1 wt % | | | | | |
| 2B | Arg - | 8 | 4 psi | 9 ± 3 | 18 ± 8 | 0.5 |
| | 2 wt % | | | | | |
| | Pico - | | | | | |
| | 1 wt % | | | | | |
| 2C | LysHCL - | 8 | 2 psi | 4 ± 3 | 31 ± 11 | 0.13 |
| | 2 wt % | | | | | |
| | Pico - | | | | | |
| | 0.5 wt % | | | | | |
| 2D | LysHCL - | 8 | 2 psi | 11 ± 4 | 26 ± 8 | 0.42 |
| | 3 wt % | | | | | |
| | Pico - | | | | | |
| | 1 wt % | | | | | |
| 2E | LysHCL - | 8 | 2 psi | 16 ± 4 | 37 ± 6 | 0.43 |
| | 2 wt % | | | | | |
| | Pico - | | | | | |
| | 1 wt % | | | | | |

In Sample 2C, a silicon nitride to silicon dioxide selectivity of nearly 8:1 was achieved. Applicants hypothesize that when the CMP slurry comprises lysine mono hydrochloride in combination with picolinic acid at a pH of 8, the lysine mono hydrochloride is positively charged and adsorbs onto the surface of both the colloidal silica abrasive particles and the silicon dioxide film surface. Electrostatic repulsion suppresses the silicon dioxide removal rate. The lysine coated silica abrasive enhances the silicon nitride removal rate. Picolinic acid, which has a pKa of about 6, adsorbs on the silicon nitride film surface, and here again the silica abrasives when used with picolinic acid in the slurry result in increased silicon nitride removal rates.

Additional advantages and modifications will readily occur to those skilled in the art. Therefore, the invention in its broader aspects is not limited to the specific details and illustrative examples shown and described herein. Accordingly, various modifications may be made without departing from the spirit or scope of the general inventive concept as defined by the appended claims and their equivalents.

1-7. (canceled)

8. A method for removing silicon nitride from a surface at a greater rate than silicon dioxide is removed from the surface, the method comprising:
a) providing a polishing slurry having a pH of about 9±0.5, said polishing slurry comprising colloidal silica abrasive particles dispersed in water together with an additive comprising a first compound and a second compound, wherein said first compound comprises a organic compound containing an alpha-amino acid functional group and a guanidine group and said second compound comprises picolinic acid or a derivative thereof
b) disposing the polishing slurry between a polishing pad and the surface; and
c) pressing the polishing pad against the surface while the polishing pad and surface are moving relative to each other with the polishing slurry disposed therebetween to remove silicon nitride from the surface at a greater rate than silicon dioxide is removed from the surface.

9. The method according to claim 8 wherein said first compound comprises arginine.

10. (canceled)

11. The method according to claim 8 wherein the polishing slurry comprises from about 5% to about 15% by weight of silica particles having a mean average diameter of from about 25 nm to about 75 nm.

12. The method according to claim 8 wherein the polishing slurry comprises from about 1.0% to about 4.0% by weight of said first compound.

13. The method according to claim 9 wherein the polishing slurry comprises about 10% by weight of silica particles having a mean average diameter of about 50 nm and from about 1% to about 3% by weight of arginine.

14. The method according to claim 8 wherein the polishing slurry comprises from about 1.0% to about 3.0% by weight of picolinic acid.

15-19. (canceled)
